(19) United States
(12) Patent Application Publication
(10) Pub. No.: US 2023/0180547 A1
(43) Pub. Date: Jun. 8, 2023

(54) DISPLAY PANEL AND DISPLAY DEVICE

(71) Applicant: BOE Technology Group Co., Ltd., Beijing (CN)

(72) Inventors: Pan XU, Beijing (CN); Li SUN, Beijing (CN); Dacheng ZHANG, Beijing (CN); Lang LIU, Beijing (CN); Chen XU, Beijing (CN); Yongqian LI, Beijing (CN)

(21) Appl. No.: 17/416,481

(22) PCT Filed: Dec. 29, 2020
(86) PCT No.: PCT/CN2020/141130

§ 371 Date: Jun. 19, 2021

(30) Foreign Application Priority Data
Mar. 18, 2020 (CN) 202010191644.9

(51) Int. Cl. H10K 59/131; G02F 1/1362

(52) U.S. Cl. CPC H10K 59/131; G02F 1/136286

(57) ABSTRACT

A display panel and a display device are provided, since a plurality of source ICs (01) are arranged, a large-sized display panel is driven, and since the plurality of source ICs (01) are scattered around a display area (A) along the tangential directions of the edge of the display area (A), that is, the source ICs (01) are distributed according to the shape of the display panel, a distance between the source ICs (01) and the display area (A) is shortened, and thus a narrow bezel design of the display panel is facilitated.

### FIELD

The present disclosure relates to the technical field of display, in particular to a display panel and a display device.

### BACKGROUND

With the rapid development of display technology, in addition to traditional information display and other functions of a display, in order to better adapt to the overall structure and use requirements of the environment, the requirements on the appearance are gradually increasing, and special-shaped displays are produced.

Special-shaped displays are displays in special shapes modified on the basis of traditional displays, so that the characteristics of the displays can better adapt to the overall structure of buildings and the environment. At present, the structural forms of common special-shaped screens mainly include a fan shape, an arc shape, a circle, a cylinder, a triangle and other structural forms. Currently, most of the special-shaped displays on the market are driven by a single source IC, which has certain restrictions on the size of the displays. Once the size of the displays is relatively large, it is difficult to drive the displays by a single source IC.

### SUMMARY

Embodiments of the present disclosure provide a display panel and a display device, and the specific solutions are as follows.

on one hand, embodiments of the present disclosure provide a display panel, the display panel includes:

a display area, and

a bezel area surrounding the display area;

the display area is provided with a plurality of pixels and a plurality of data lines, extending along a first direction, arranged along a second direction, and configured to provide data signals to the pixels; and

the bezel area is provided with a plurality of source ICs, configured to provide the data signals to the data lines in the display area;

the plurality of source ICs are dispersedly arranged, around the display area, and the source ICs are arranged along directions of tangent lines at edges of the display area.

Optionally, in the display panel provided by the embodiments of the disclosure, the first direction is perpendicular to the second direction; and the plurality of source ICs arranged along the directions of tangent lines at the edges of the display area are arranged at the edges of the tangent lines in the first direction or the second direction.

Optionally, in the display panel provided by the embodiments of the disclosure, the bezel area is provided with four source ICs; and extension lines, along arrangement directions of the four source ICs, of the four source ICs form a rectangle, and the display area is in the rectangle.

Optionally, in the display panel provided by the embodiments of the disclosure, the bezel area is provided with three source ICs; and two of the three source ICs are respectively on the two opposite sides of the display area and arranged in parallel, and an arrangement direction of one, other than the two, of the three source ICs is perpendicular to an arrangement direction of the two source ICs.

Optionally, in the display panel provided by the embodiment of the disclosure, the bezel area is provided with two source ICs; and the two source ICs are respectively located on the two opposite sides of the display area and arranged in parallel.

Optionally, in the display panel provided by the embodiments of the disclosure, the display area includes a plurality of display sub-areas arranged along the second direction; and each of the plurality of source ICs is connected to corresponding data lines in one or two display sub-areas adjacent to the each source IC.

Optionally, in the display panel provided by the embodiments of the disclosure, the plurality of source ICs are connected to the data lines through lead lines; and lead lines connected to the each source IC are respectively led out from the two ends of the each source IC and then connected to the corresponding data lines in the one or two display sub-areas.

Optionally, in the display panel provided by the embodiments of the disclosure, a length of the lead line is negatively correlated with a length of the data line connected to the lead line, and the longer the data line, the shorter the lead line connected to the data line.

Optionally, in the display panel provided by the embodiments of the disclosure, the display area is of an axisymmetric shape, and an axis of symmetry of the axisymmetric shape extends in the first direction or the second direction.

Optionally, in the display panel provided by the embodiments of the disclosure, the shape of the display area is a circle, an ellipse, a fan, a peach heart, a triangle or an N-gon, and N is greater than 4.

Optionally, in the display panel provided by the embodiment of the disclosure, the display panel is an OLED display panel or a liquid crystal display panel.

On the other hand, the embodiments of the present disclosure further provide a display device including any one of the above-mentioned display panels provided by the embodiments of the present disclosure.

### BRIEF DESCRIPTION OF THE DRAWINGS

FIG. 1 is a structural schematic diagram of a special-shaped display in the related art.

FIG. 2 is a schematic structural diagram of a display panel provided by an embodiment of the present disclosure.

FIG. 3 is a schematic structural diagram of another display panel provided by an embodiment of the present disclosure.

FIG. 4 is a rectangular area corresponding to a display area when the display panel shown in FIG. 3 is prepared.

FIG. 5 is a schematic structural diagram of another display panel provided by an embodiment of the present disclosure.

FIG. 6 is a rectangular area corresponding to a display area when the display panel shown in FIG. 5 is prepared.

FIG. 7 is a schematic structural diagram of another display panel provided by an embodiment of the present disclosure.

FIG. 8 is a schematic structural diagram of another display panel provided by an embodiment of the present disclosure.

FIG. 9 is a schematic structural diagram of another display panel provided by an embodiment of the present disclosure.

### DETAILED DESCRIPTION OF THE EMBODIMENTS

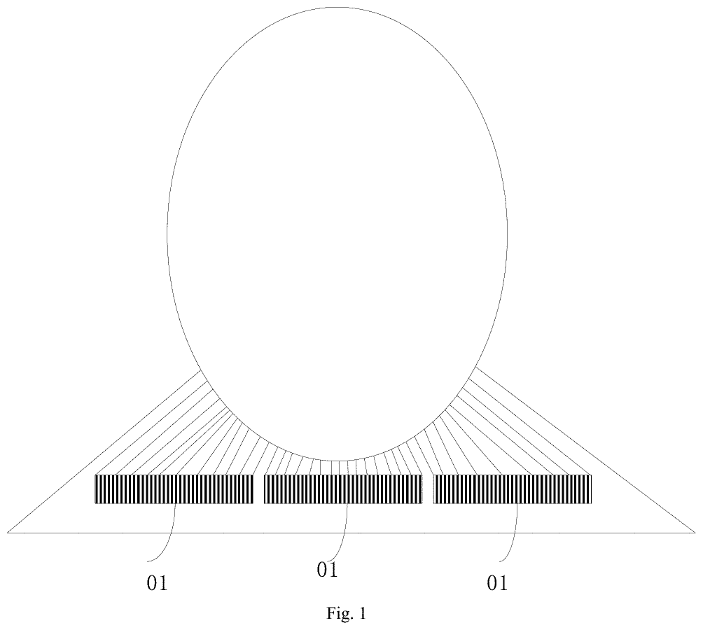

In the related art, for a large-sized special-shaped display, as shown in FIG. 1, multiple source ICs 01 are arranged side by side on a base of a display screen, which results in a wide bottom bezel of the special-shaped display.

In view of this, embodiments of the present disclosure provide a display panel and a display device for reducing the bezel width of a large-sized display.

In order to make the above-mentioned objectives, features and advantages of the present disclosure more obvious and understandable, the present disclosure will be further described below with reference to the accompanying drawings and embodiments. However, the exemplary embodiments can be implemented in various forms, and should not be construed as being limited to the embodiments set forth herein; on the contrary, by providing these embodiments, the present disclosure is made more comprehensive and complete, and the concept of the exemplary embodiments is fully conveyed to those skilled in the art. The same reference numerals in the figures indicate the same or similar structures, and thus their repeated description will be omitted. The words expressing positions and directions described in the present disclosure are all illustrated by taking the accompanying drawings as examples, but changes can also be made according to needs, and the changes are all included in the protection scope of the present disclosure. The accompanying drawings of the present disclosure are only used to illustrate the relative position relationship and do not represent the true scale.

It should be noted that specific details are set forth in the following description in order to fully understand the present disclosure. However, the present disclosure can be implemented in a variety of other ways different from those described herein, and those skilled in the art can do similar promotion without departing from the connotation of the present disclosure. Therefore, the present disclosure is not limited by the specific embodiments disclosed below. The following description of the specification is preferred embodiments for implementing the application, but the description is for the purpose of explaining the general principles of the application, and is not intended to limit the scope of the application. The protection scope of the application shall be subject to those defined by the appended claims.

The display panel and the display device provided by the embodiments of the present disclosure will be described in detail below with reference to the accompanying drawings.

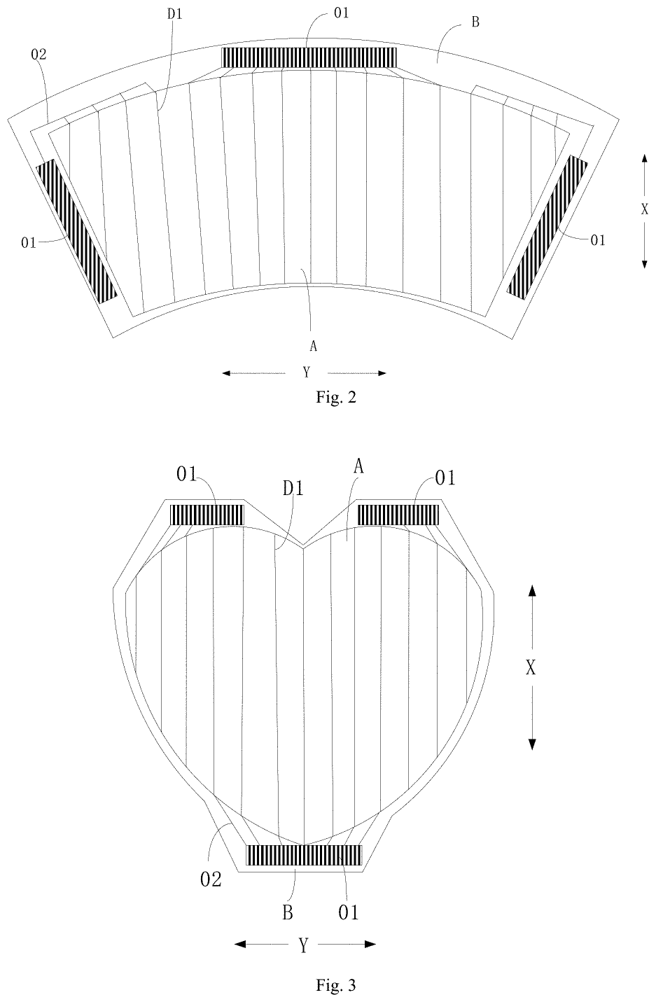

Embodiment of the present disclosure provides a display panel, wherein, as shown in FIG. 2, the display panel includes a display area A and a bezel area B surrounding the display area;

the display area A is provided with a plurality of pixels (not shown in the figure) and a plurality of data lines D1, extend along a first direction X, arranged along a second direction Y, and the plurality of the date lines are configured to provide data signals to the pixels; and

the bezel area B is provided with a plurality of source ICs 01 which are configured to provide the data signals to the data lines D1 in the display area A, and the plurality of the source ICs 01 are dispersedly arranged around the display area A, and the source ICs are arranged along directions of tangent lines at edges of the display area A.

According to the display panel provided by the embodiments of the present disclosure, since the plurality of the source ICs are arranged, a large-sized display panel can be driven, and since the plurality of the source ICs are dispersedly arranged around the display area, and the source ICs are arranged along directions of tangent lines at edges of the display area, that is, the plurality of source ICs are distributed according to the shape of the display panel, the distance between the plurality of source ICs and the display area is shortened, and thus the narrow bezel design of the display panel is facilitated.

In specific implementation, the display panel provided by the embodiments of the present disclosure is particularly applicable to the field of special-shaped display, that is, when the shape of the display area of the display panel provided by the embodiments of the present disclosure is a non-rectangular special shape, the effect is better than that of existing display panels. In the specific embodiments and the drawings in the specification provided below in the present disclosure, the display area in a special shape is taken as an example for description.

In specific implementation, the display panel provided by the embodiments of the present disclosure may be an OLED display panel, or a liquid crystal display panel, and of course, may also be electronic paper and the like, which is not limited herein.

In specific implementation, for an OLED display panel, a vapor-deposition process or an inkjet printing process is generally required when an organic light-emitting layer is prepared. However, a general vapor-deposition mask requires metal strips to tension a net plate, and the metal strips for tensioning the net plate are generally horizontal and vertical straight strips, so a vapor-deposition area needs to be a standard rectangle. It is not only difficult, but also expensive to realize a situation that a vapor-deposition area is of a special shape. The traditional inkjet printing technology is limited to equipment and software, and can only correspond to standard rectangular printing areas. Otherwise, it is difficult to correspond to the equipment and software for special-shaped printing, and the production time is very long, which is not conducive to mass production.

In the display panel provided by the embodiments of the present disclosure, by setting the positions of the source ICs, a rectangular vapor-deposition area or printing area can be realized, and the area where the source ICs are arranged can be avoided. The special-shaped display panel provided by the embodiment of the present disclosure is described below through specific embodiments.

Optionally, in the display panel provided by the embodiments of the present disclosure, as shown in FIG. 3, the first direction X is perpendicular to the second direction Y; and the plurality of source ICs 01 arranged along the directions of tangent lines at the edges of the display area A are arranged at the edges of the tangent lines in the first direction X or the second direction Y.

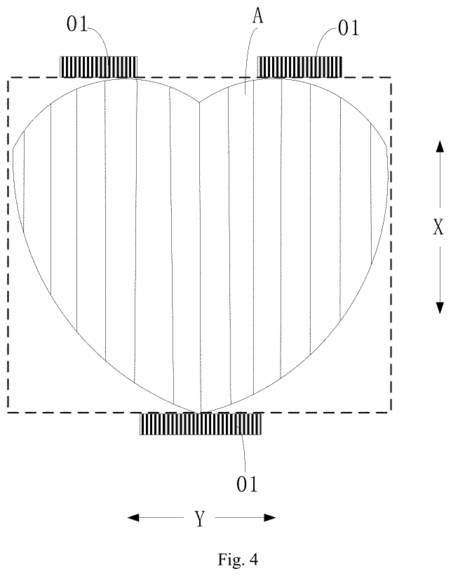

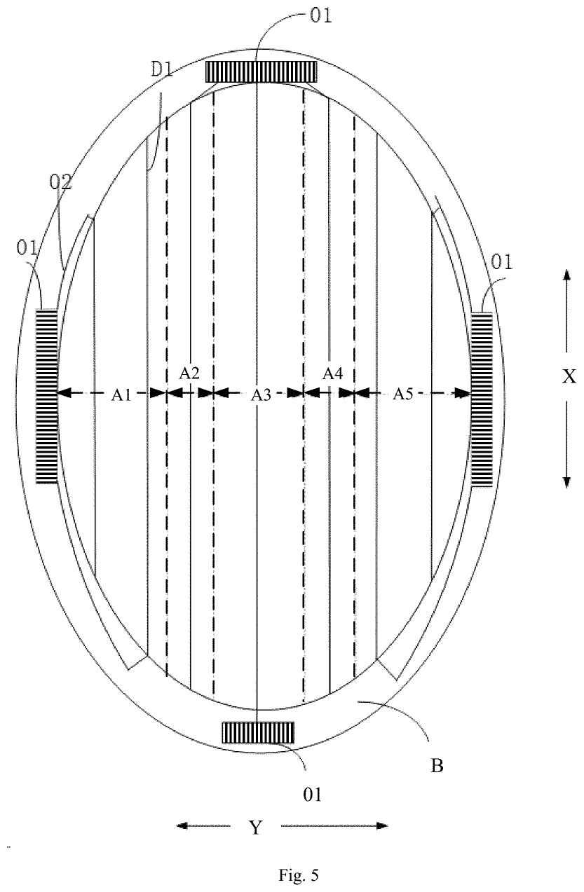

As shown in FIG. 4, an area enclosed by the plurality of source ICs 01 is a rectangular area (a dashed rectangular box in the figure). Even if the special-shaped display panel is an OLED display panel, a rectangular vapor-deposition area or printing area can be realized, the plurality of source ICs 01 are not covered by the vapor-deposition area or the printing area, thus the traditional printing or vapor-deposition process can also meet the requirements for preparation of the special-shaped display panel.

It should be noted that, in the display panel provided by the embodiments of the present disclosure, the arrangement direction of the plurality of source ICs refers to the extension direction of the plurality of source ICs. For example, in FIG. 3, the extension direction of the three source ICs 01 is in the second direction Y, and the arrangement direction of the three source ICs 01 is also in the second direction Y.

Accordingly, taking the shape of the display area as an ellipse as an example below to illustrate the display panel provided by the embodiment of the present disclosure.

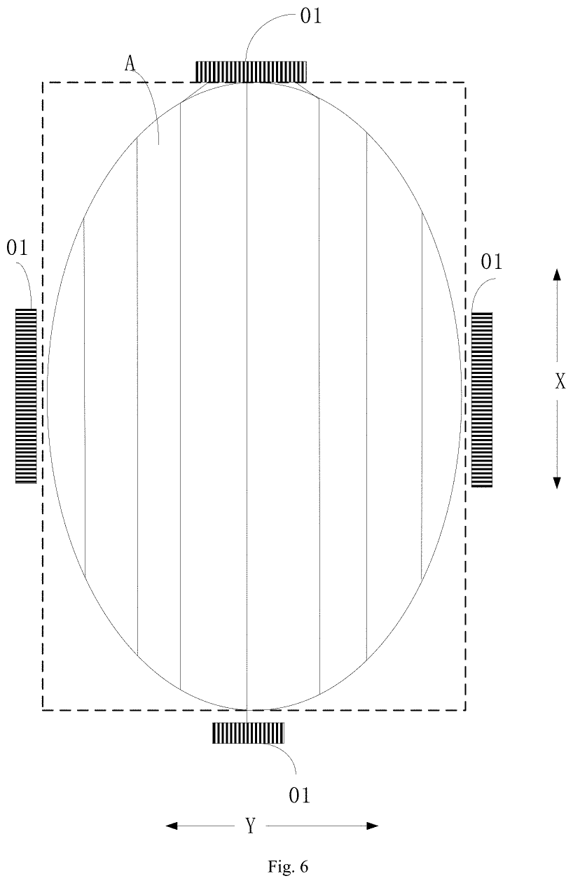

In one of the embodiments, in the display panel provided by the embodiments of the present disclosure, as shown in FIG. 5 and FIG. 6, the bezel area B is provided with four source ICs 01; and extension lines, along arrangement directions of the four source ICs, of the four source ICs 01 form a rectangle (a dashed box in FIG. 6), and the display area A is in the rectangle.

In some embodiments, the above-mentioned special-shaped display panel is applicable to a large-sized display panel, and the display panel is provided with the plurality of pixels and requires a high driving capability. In this way, four source ICs are arranged in the bezel area of the special-shaped display panel, and the area enclosed by the four source ICs is a rectangular area, in the case that the special-shaped display panel is an OLED display panel, a rectangular vapor-deposition area or printing area can be realized, the source ICs are not covered by the vapor-deposition area or the printing area, thus the traditional printing or vapor-deposition process can also meet the requirements for preparation of the special-shaped display panel. In addition, the four source ICs are dispersedly arranged along the directions of the tangent lines at the edges of the special-shaped display area to ensure a small bezel width.

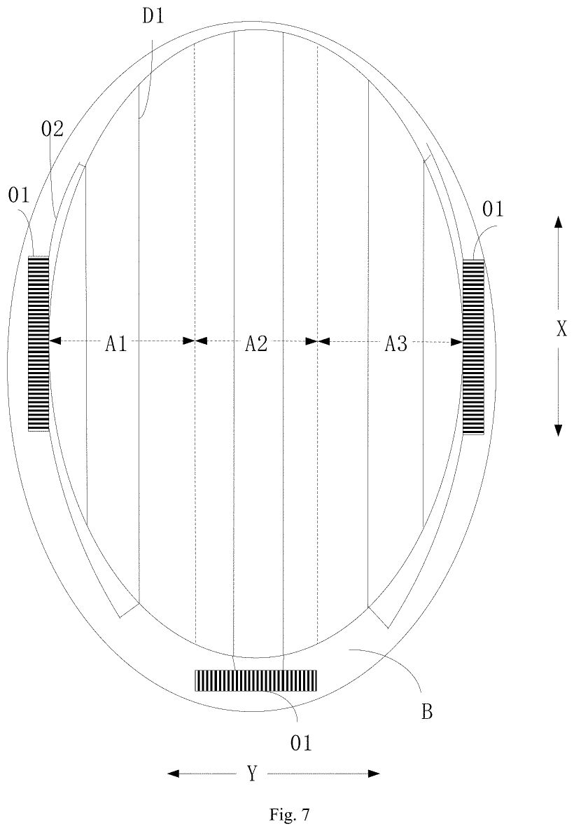

In another embodiment, in the display panel provided by the embodiment of the present disclosure, as shown in FIG. 7, the bezel area B is provided with three source ICs 01; and two of the three source ICs 01 are respectively located on two opposite sides of the display area A and arranged in parallel, and the arrangement direction of the one, other than the two, of the three source ICs 01 is perpendicular to an arrangement direction of the two source ICs 01.

Accordingly, when the size of the special-shaped display panel is not particularly large, three source ICs may be arranged, and the bezel width can be reduced by reducing the number of the source ICs, in addition, the area enclosed by the three source ICs is a rectangular area, in the case that the special-shaped display panel is an OLED display panel, a rectangular vapor-deposition area or printing area can be realized, the source ICs are not covered by the vapor-deposition area or the printing area, thus the traditional printing or vapor-deposition process can also meet the requirements for preparation of the special-shaped display panel.

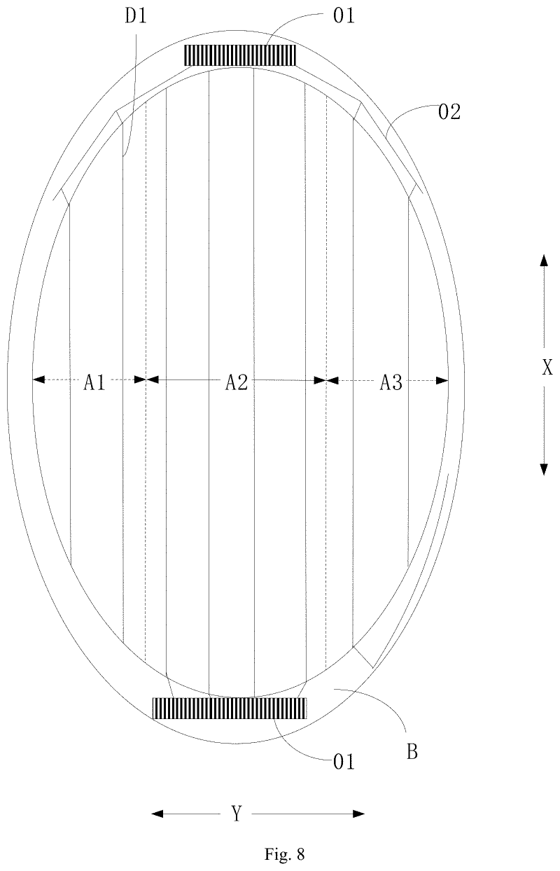

In another embodiment, in the display panel provided by the embodiment of the present disclosure, as shown in FIG. 8, the bezel area B is provided with two source ICs 01; and the two source ICs 01 are respectively located on the two opposite sides of the display area A and arranged in parallel.

In some embodiments, when the size of the special-shaped display panel is not particularly large, two source ICs may also be arranged, and the bezel width can be reduced by reducing the number of the source ICs, in addition, the area enclosed by the two source ICs is a rectangular area, in the case that the special-shaped display panel is an OLED display panel, a rectangular vapor-deposition area or printing area can be realized, the source ICs are not covered by the vapor-deposition area or the printing area, thus the traditional printing or vapor-deposition process can also meet the requirements for preparation of the special-shaped display panel.

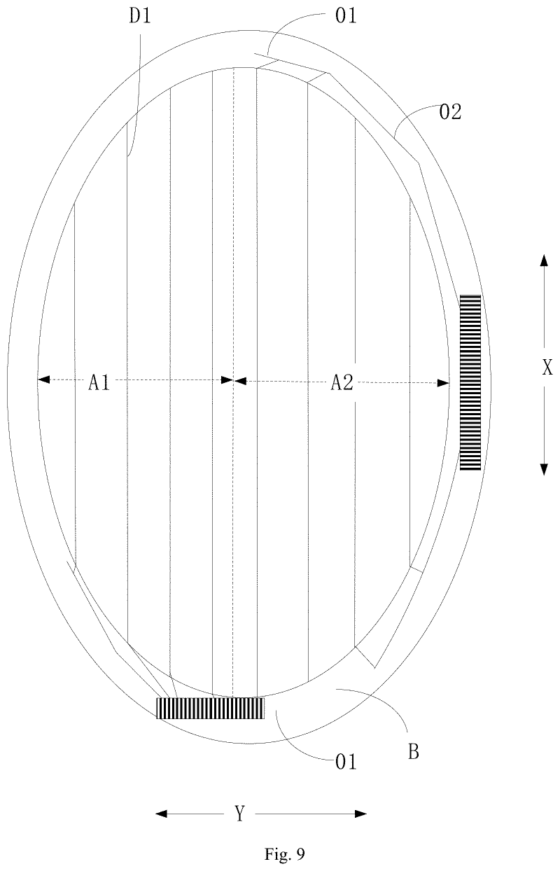

Certainly, in specific implementation, in the display panel provided by the embodiment of the present disclosure, as shown in FIG. 9, when two source ICs 01 are arranged in the bezel area B, one of the two source ICs 01 may be arranged along the first direction X, and the another one of the two source IC 01 may be arranged along the second direction Y, so that the area enclosed by the two source ICs is a rectangular area, in the case that the special-shaped display panel is an OLED display panel, a rectangular vapor-deposition area or printing area can be realized, the source ICs are not covered by the vapor-deposition area or the printing area, thus the traditional printing or vapor-deposition process can also meet the requirements for preparation of the special-shaped display panel.

It should be noted that the number of the source ICs in the display panel can be determined according to the size of the display panel. The larger the display panel, the higher the driving capability required, and the more ICs that need to be arranged.

Optionally, in the display panel provided by the embodiments of the present disclosure, as shown in FIG. 5 and FIGS. 7 to 9, the display area A includes a plurality of display sub-areas A1 to AN arranged along the second direction Y; and each source IC 01 is connected to corresponding data lines D1 in one or two display sub-areas An adjacent to the each source IC. In this way, the each source IC 01 is connected to the corresponding data line D1 in the display sub-area adjacent to the each source IC, then the source ICs 01 can be closer to the connected data lines D1, and therefore the bezel width can be further reduced.

Optionally, in the display panel provided by the embodiment of the present disclosure, as shown in FIG. 5 and FIGS. 7 to 9, the source ICs 01 are connected to the data lines D1 through lead lines 02; and the lead lines 02 connected to the each source IC 01 are respectively led out from the two ends of the each source IC 01 and then connected to the corresponding data lines D1 in the one or two display sub-areas An. In this way, all the lead lines 02 can be prevented from being gathered at one ends of the source ICs 01, so that the bezel width can be further reduced.

In specific implementation, due to the inconsistent lengths of the data lines of the special-shaped display panel, the numbers of pixels connected to the data lines of different lengths are not equal, the loads of the data lines of different lengths are different, and the load difference affects the display effect. Therefore, optionally, in the display panel provided by the embodiment of the present disclosure, the length of the lead lines is negatively correlated with the length of the data lines connected to the lead lines. The longer the data lines, the shorter the lead lines connected to the data lines. That is, the difference in the length of the lead lines is used to compensate for the load difference of the data lines.

Optionally, in the display panel provided by the embodiment of the present disclosure, as shown in FIGS. 2 to 9, the display area A is of an axisymmetric shape, and an axis of symmetry of the axisymmetric shape extends in the first direction X or the second direction Y. For example, the shape of the display area A is a circle, an ellipse, a fan, a peach heart, a triangle or an N-gon (N is an integer greater than 4), which is not limited herein.

Based on the same inventive concept, embodiments of the present disclosure further provide a display device, including any one of the above-mentioned display panels provided by the embodiments of the present disclosure. Since the principle of solving the problems of the display device is similar to that of the aforementioned display panel, the implementation of the display device can refer to the implementation of the aforementioned display panel, and the repeated parts are not described in detail herein.

According to the display panel and the display device provided by the embodiments of the present disclosure, since the plurality of the source ICs are arranged, a large-sized display panel is driven, and since the plurality of the source ICs are dispersedly arranged around the display area, and the source ICs are arranged along directions of tangent lines at edges of the display area, that is, the source ICs are distributed according to the shape of the display panel, the distance between the source ICs and the display area is shortened, and thus the narrow bezel design of the display panel is facilitated.

Apparently, those skilled in the art can make various modifications and variations to the present disclosure without departing from the spirit and scope of the present disclosure. In this way, if these modifications and variations of the present disclosure fall within the scope of the claims of the present disclosure and their equivalent technologies, the present disclosure is also intended to include these modifications and variations.

1. A display panel, comprising:
a display area; and
a non-display area surrounding the display area;
wherein the display area is provided with:
a plurality of pixels; and
a plurality of data lines, extending along a first direction, arranged along a second direction, and configured to provide data signals to the pixels; and
the non-display area is provided with:
a plurality of source Integrated Circuits (ICs), configured to provide the data signals to the data lines in the display area;
wherein the plurality of source ICs are dispersedly arranged around the display area, and the source ICs each is arranged along a direction of a tangent line at an edge point of the display area.

2. The display panel of claim 1, wherein:
the first direction is perpendicular to the second direction; and
the edge point of the display area at which the each source IC is arranged along the direction of the tangent line is an edge point in the first direction or the second direction.

3. The display panel of claim 2, wherein:
the non-display area is provided with four source ICs; and
extension lines, along arrangement directions of the four source ICs, of the four source ICs form a rectangle, and the display area is in the rectangle.

4. The display panel of claim 2, wherein:
the non-display area is provided with three source ICs; and
two of the three source ICs are respectively located on two opposite sides of the display area and arranged in parallel, and an arrangement direction of one, other than the two, of the three source ICs is perpendicular to an arrangement direction of the two source ICs.

5. The display panel of claim 2, wherein:
the non-display area is provided with two source ICs; and
the two source ICs are respectively located on the two opposite sides of the display area and arranged in parallel.

6. The display panel of claim 2, wherein:
the display area comprises a plurality of display sub-areas arranged along the second direction; and
each of the plurality of source ICs is connected to corresponding data lines in one or two display sub-areas adjacent to the each source IC.

7. The display panel of claim 6, wherein:
the plurality of source ICs are connected to the data lines through lead lines; and
lead lines connected to the each source IC are respectively led out from two ends of the each source IC and then connected to the corresponding data lines in the one or two display sub-areas.

8. The display panel of claim 7, wherein a length of the lead line is negatively correlated with a length of the data line connected to the lead line, and the longer the data line, the shorter the lead line connected to the data line.

9. The display panel of claim 1, wherein the display area is of an axisymmetric shape, and an axis of symmetry of the axisymmetric shape extends in the first direction or the second direction.

10. The display panel of claim 9, wherein the shape of the display area is a circle, an ellipse, a fan, a peach heart, a triangle or an N-gon, and N is greater than 4.

11. The display panel of claim 1, wherein the display panel is an OLED display panel or a liquid crystal display panel.

12. A display device, comprising a display panel, wherein the display panel comprises:
a display area; and
a non-display area surrounding the display area;
wherein the display area is provided with:
a plurality of pixels; and
a plurality of data lines, extending along a first direction, arranged along a second direction, and configured to provide data signals to the pixels; and
the non-display area is provided with:
a plurality of source Integrated Circuits (ICs), configured to provide the data signals to the data lines in the display area;
wherein the plurality of source ICs are dispersedly arranged around the display area, and the source ICs each is arranged along a direction of tangent line at an edge point of the display area.

13. The display device of claim 12, wherein:
the first direction is perpendicular to the second direction; and
the edge point of the display area at which the each source IC is arranged along the direction of the tangent line is an edge point in the first direction or the second direction.

14. The display device of claim 13, wherein:
the non-display area is provided with four source ICs; and
extension lines, along arrangement directions of the four source ICs, of the four source ICs form a rectangle, and the display area is in the rectangle.

15. The display device of claim 13, wherein:
the non-display area is provided with three source ICs; and
two of the three source ICs are respectively located on two opposite sides of the display area and arranged in parallel, and an arrangement direction of one, other than the two, of the three source ICs is perpendicular to an arrangement direction of the two source ICs.

16. The display device of claim 13, wherein:
the non-display area is provided with two source ICs; and
the two source ICs are respectively located on the two opposite sides of the display area and arranged in parallel.

17. The display device of claim 13, wherein:
the display area comprises a plurality of display sub-areas arranged along the second direction; and
each of the plurality of source ICs is connected to corresponding data lines in one or two display sub-areas adjacent to the each source IC.

18. The display device of claim 17, wherein:
the plurality of source ICs are connected to the data lines through lead lines; and
lead lines connected to the each source IC are respectively led out from two ends of the each source IC and then connected to the corresponding data lines in the one or two display sub-areas.

19. The display device of claim 18, wherein a length of the lead line is negatively correlated with a length of the data line connected to the lead line, and the longer the data line, the shorter the lead line connected to the data line.

20. The display device of claim 12, wherein the display area is of an axisymmetric shape, and an axis of symmetry of the axisymmetric shape extends in the first direction or the second direction.
